(19) United States
(12) Patent Application Publication
(10) Pub. No.: US 2026/0090045 A1
(43) Pub. Date: Mar. 26, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Shunsuke ASABA, Himeji Hyogo (JP); Hiroshi KONO, Himeji Hyogo (JP)

(21) Appl. No.: 19/070,436

(22) Filed: Mar. 4, 2025

(30) Foreign Application Priority Data
Sep. 24, 2024 (JP) 2024-164904

(51) Int. Cl. H10D 62/17; H10D 30/66; H10D 62/10; H10D 62/832

(52) U.S. Cl. CPC H10D 62/393; H10D 30/66; H10D 62/127; H10D 62/8325

(57) ABSTRACT

A semiconductor device of embodiments includes: a silicon carbide layer including first conductive type first silicon carbide region, second conductive type second, third and fourth silicon carbide regions extending in a first direction on the first silicon carbide region, first conductive type fifth and sixth silicon carbide regions on the second and third silicon carbide region, respectively, second conductive type eighth silicon carbide region of the between the second and the third silicon carbide region, and second conductive type ninth silicon carbide region of the second conductive type between the second and the third silicon carbide region and spaced apart from the eighth silicon carbide region in the first direction; a first electrode including a first portion in contact with the eighth silicon carbide region and a second portion in contact with the ninth silicon carbide region; a gate electrode surrounding the first and second portions; and a second electrode.

### CROSS-REFERENCE TO RELATED APPLICATION

This application is based upon and claims the benefit of priority from Japanese Patent Application No. 2024-164904, filed on Sep. 24, 2024, the entire contents of which are incorporated herein by reference.

### FIELD

Embodiments described herein relate generally to a semiconductor device.

### BACKGROUND

Silicon carbide is a material for semiconductor devices. Silicon carbide has excellent physical properties, such as a bandgap of about 3 times that of silicon, a breakdown field strength of about 10 times that of silicon, and a thermal conductivity of about 3 times that of silicon. By using such characteristics, for example, it is possible to realize a metal oxide semiconductor field effect transistor (MOSFET) that has a high breakdown voltage and low loss and that can operate at high temperature. In order to improve the characteristics of a vertical MOSFET using silicon carbide, it is desirable to reduce the on-resistance of the MOSFET.

### BRIEF DESCRIPTION OF THE DRAWINGS

FIG. 1 is a schematic cross-sectional view of a semiconductor device according to a first embodiment;

FIG. 2 is a schematic cross-sectional view of the semiconductor device according to the first embodiment;

FIG. 3 is a schematic cross-sectional view of the semiconductor device according to the first embodiment;

FIG. 4 is a schematic top view of the semiconductor device according to the first embodiment;

FIG. 5 is a schematic top view of the semiconductor device according to the first embodiment;

FIG. 6 is a schematic cross-sectional view of a semiconductor device according to a comparative example;

FIG. 7 is a schematic top view of a semiconductor device according to a comparative example;

FIG. 8 is a schematic top view of a semiconductor device according to a comparative example;

FIG. 9 is a schematic cross-sectional view of a semiconductor device according to a first modification example of the first embodiment;

FIG. 10 is a schematic cross-sectional view of a semiconductor device according to a second modification example of the first embodiment;

FIG. 11 is a schematic cross-sectional view of a semiconductor device according to a second embodiment;

FIG. 12 is a schematic cross-sectional view of the semiconductor device according to the second embodiment;

FIG. 13 is a schematic cross-sectional view of the semiconductor device according to the second embodiment;

FIG. 14 is a schematic top view of the semiconductor device according to the second embodiment;

FIG. 15 is a schematic top view of the semiconductor device according to the second embodiment;

FIG. 16 is a schematic cross-sectional view of a semiconductor device according to a third embodiment;

FIG. 17 is a schematic cross-sectional view of the semiconductor device according to the third embodiment;

FIG. 18 is a schematic cross-sectional view of the semiconductor device according to the third embodiment;

FIG. 19 is a schematic top view of the semiconductor device according to the third embodiment; and

FIG. 20 is a schematic top view of the semiconductor device according to the third embodiment.

### DETAILED DESCRIPTION

A semiconductor device of embodiments includes: a silicon carbide layer having a first face and a second face opposite to the first face and including a first silicon carbide region of a first conductive type, a second silicon carbide region of a second conductive type provided between the first silicon carbide region and the first face and extending in a first direction parallel to the first face, a third silicon carbide region of a second conductive type provided between the first silicon carbide region and the first face, extending in the first direction, and spaced apart from the second silicon carbide region in a second direction parallel to the first face and perpendicular to the first direction, a fourth silicon carbide region of the second conductive type provided between the first silicon carbide region and the first face, extending in the first direction, and spaced apart from the third silicon carbide region in the second direction, a fifth silicon carbide region of the first conductive type provided between the second silicon carbide region and the first face and extending in the first direction, a sixth silicon carbide region of the first conductive type provided between the third silicon carbide region and the first face and extending in the first direction, a seventh silicon carbide region of the first conductive type provided between the fourth silicon carbide region and the first face and extending in the first direction, an eighth silicon carbide region of the second conductive type provided between the first silicon carbide region and the first face, provided between the second silicon carbide region and the third silicon carbide region, and in contact with the second silicon carbide region and the third silicon carbide region, and a ninth silicon carbide region of the second conductive type provided between the first silicon carbide region and the first face, provided between the second silicon carbide region and the third silicon carbide region, in contact with the second silicon carbide region and the third silicon carbide region, and spaced apart from the eighth silicon carbide region in the first direction; a first electrode including a first portion in contact with the eighth silicon carbide region and a second portion in contact with the ninth silicon carbide region, electrically connected to the fifth silicon carbide region, the sixth silicon carbide region, and the seventh silicon carbide region, and provided on the first face side of the silicon carbide layer; a gate electrode facing the first silicon carbide region, the second silicon carbide region, the third silicon carbide region, the fourth silicon carbide region, the fifth silicon carbide region, the sixth silicon carbide region, and the seventh silicon carbide region and surrounding the first portion and the second portion; a gate insulating layer provided between the first silicon carbide region, the second silicon carbide region, the third silicon carbide region, the fourth silicon carbide region, the fifth silicon carbide region, the sixth silicon carbide region, and the seventh silicon carbide region and the gate electrode; and a second electrode provided on the second face side of the silicon carbide layer.

Hereinafter, embodiments will be described with reference to the diagrams. In the following description, the same or similar members and the like may be denoted by the same reference numerals, and the description of the members and the like once described may be omitted as appropriate.

In addition, in the following description, when there are notations of n⁺, n, n⁻, p⁺, p, and p⁻, these notations indicate the relative high and low of the impurity concentration in each conductive type. That is, n⁺ indicates that the n-type impurity concentration is relatively higher than n, and n⁻ indicates that the n-type impurity concentration is relatively lower than n. In addition, p⁺ indicates that the p-type impurity concentration is relatively higher than p, and p⁻ indicates that the p-type impurity concentration is relatively lower than p. In addition, n⁺-type and n⁻-type may be simply described as n-type, p⁺-type and p⁻-type may be simply described as p-type.

The impurity concentration can be measured by, for example, secondary ion mass spectrometry (SIMS). In addition, the relative high and low of the impurity concentration can be determined from, for example, the high and low of the carrier concentration obtained by scanning capacitance microscopy (SCM). In addition, the distance such as the width or depth of an impurity region can be calculated by, for example, SIMS. In addition, the distance such as the width or depth of the impurity region can be calculated from, for example, an SCM image or an image of a scanning electron microscope (SEM). In addition, the thickness and the like of the insulating layer can be measured on, for example, an image of SIMS, SEM, or a transmission electron microscope (TEM).

In addition, in this specification, the “p-type impurity concentration” in the p-type silicon carbide region means the net p-type impurity concentration obtained by subtracting the n-type impurity concentration in the region from the p-type impurity concentration in the region. In addition, the “n-type impurity concentration” in the n-type silicon carbide region means the net n-type impurity concentration obtained by subtracting the p-type impurity concentration in the region from the n-type impurity concentration in the region.

In addition, unless otherwise specified in this specification, the impurity concentration in a specific region means the maximum impurity concentration in the region.

### First Embodiment

A semiconductor device according to a first embodiment includes a silicon carbide layer having a first face and a second face opposite to the first face. The silicon carbide layer includes: a first silicon carbide region of a first conductive type; a second silicon carbide region of a second conductive type provided between the first silicon carbide region and the first face and extending in a first direction parallel to the first face; a third silicon carbide region of a second conductive type provided between the first silicon carbide region and the first face, extending in the first direction, and spaced apart from the second silicon carbide region in a second direction parallel to the first face and perpendicular to the first direction; a fourth silicon carbide region of the second conductive type provided between the first silicon carbide region and the first face, extending in the first direction, and spaced apart from the third silicon carbide region in the second direction; a fifth silicon carbide region of the first conductive type provided between the second silicon carbide region and the first face and extending in the first direction; a sixth silicon carbide region of the first conductive type provided between the third silicon carbide region and the first face and extending in the first direction; a seventh silicon carbide region of the first conductive type provided between the fourth silicon carbide region and the first face and extending in the first direction; an eighth silicon carbide region of the second conductive type provided between the first silicon carbide region and the first face, provided between the second silicon carbide region and the third silicon carbide region, and in contact with the second silicon carbide region and the third silicon carbide region; and a ninth silicon carbide region of the second conductive type provided between the first silicon carbide region and the first face, provided between the second silicon carbide region and the third silicon carbide region, in contact with the second silicon carbide region and the third silicon carbide region, and spaced apart from the eighth silicon carbide region in the first direction. In addition, the semiconductor device according to the first embodiment includes: a first electrode including a first portion in contact with the eighth silicon carbide region and a second portion in contact with the ninth silicon carbide region, electrically connected to the fifth silicon carbide region, the sixth silicon carbide region, and the seventh silicon carbide region, and provided on the first face side of the silicon carbide layer; a gate electrode facing the first silicon carbide region, the second silicon carbide region, the third silicon carbide region, the fourth silicon carbide region, the fifth silicon carbide region, the sixth silicon carbide region, and the seventh silicon carbide region and surrounding the first portion and the second portion; a gate insulating layer provided between the first silicon carbide region, the second silicon carbide region, the third silicon carbide region, the fourth silicon carbide region, the fifth silicon carbide region, the sixth silicon carbide region, and the seventh silicon carbide region and the gate electrode; and a second electrode provided on the second face side of the silicon carbide layer.

In addition, in the semiconductor device according to the first embodiment, the silicon carbide layer further includes: a tenth silicon carbide region of the second conductive type provided between the first silicon carbide region and the first face, extending in the first direction, and spaced apart from the fourth silicon carbide region in the second direction; an eleventh silicon carbide region of the first conductive type provided between the tenth silicon carbide region and the first face and extending in the first direction; a twelfth silicon carbide region of the second conductive type provided between the first silicon carbide region and the first face, provided between the fourth silicon carbide region and the tenth silicon carbide region, and in contact with the fourth silicon carbide region and the tenth silicon carbide region; and a thirteenth silicon carbide region of the second conductive type provided between the first silicon carbide region and the first face, between the fourth silicon carbide region and the tenth silicon carbide region, in contact with the fourth silicon carbide region and the tenth silicon carbide region, and spaced apart from the twelfth silicon carbide region in the first direction. The first electrode further includes a third portion in contact with the twelfth silicon carbide region and a fourth portion in contact with the thirteenth silicon carbide region. The gate electrode surrounds the third portion and the fourth portion.

In addition, in the semiconductor device according to the first embodiment, the third portion is disposed in the second direction of the first portion, and the fourth portion is disposed in the second direction of the first portion.

The semiconductor device according to the first embodiment is a planar gate type vertical MOSFET 100 using silicon carbide. The MOSFET 100 according to the first embodiment is, for example, a double implantation MOSFET (DIMOSFET) in which a base region and a source region are formed by ion implantation.

Hereinafter, a case where the first conductive type is n-type and the second conductive type is p-type will be described as an example. The MOSFET 100 is a vertical n-channel MOSFET having electrons as carriers.

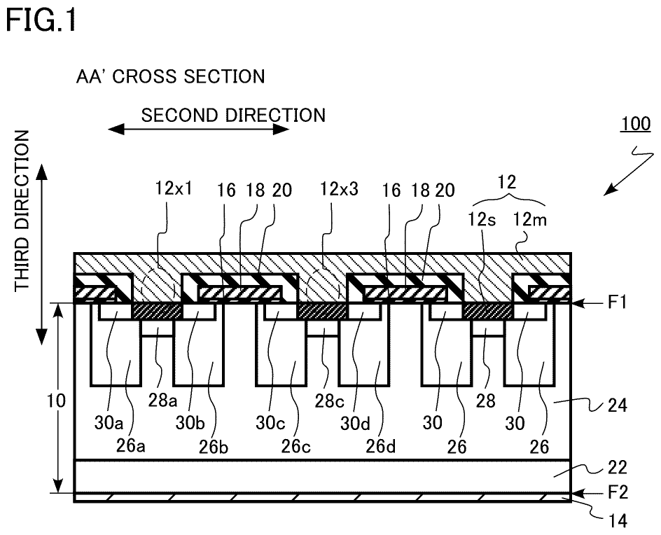

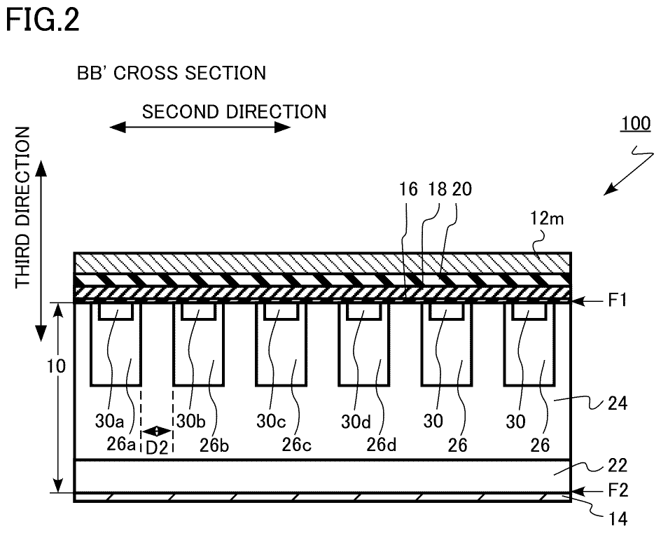

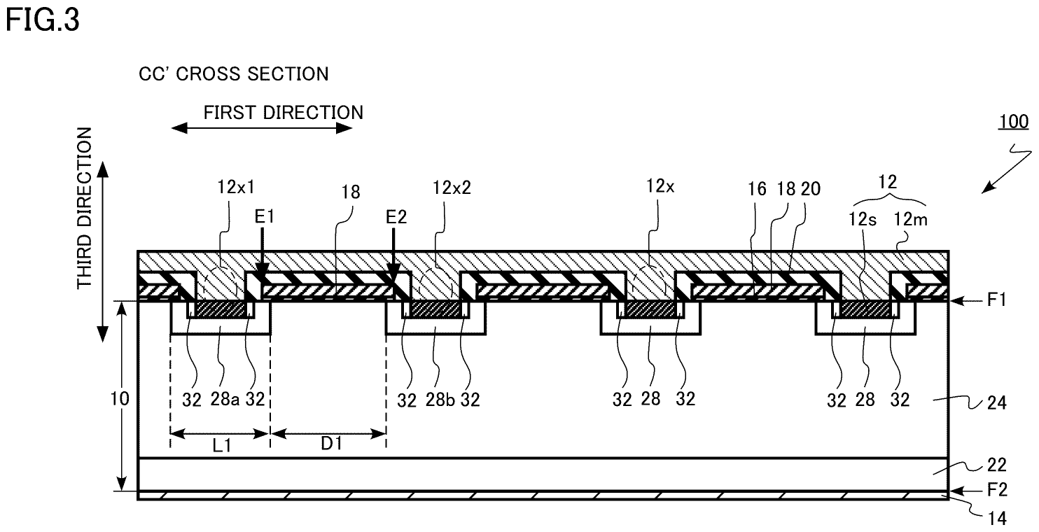

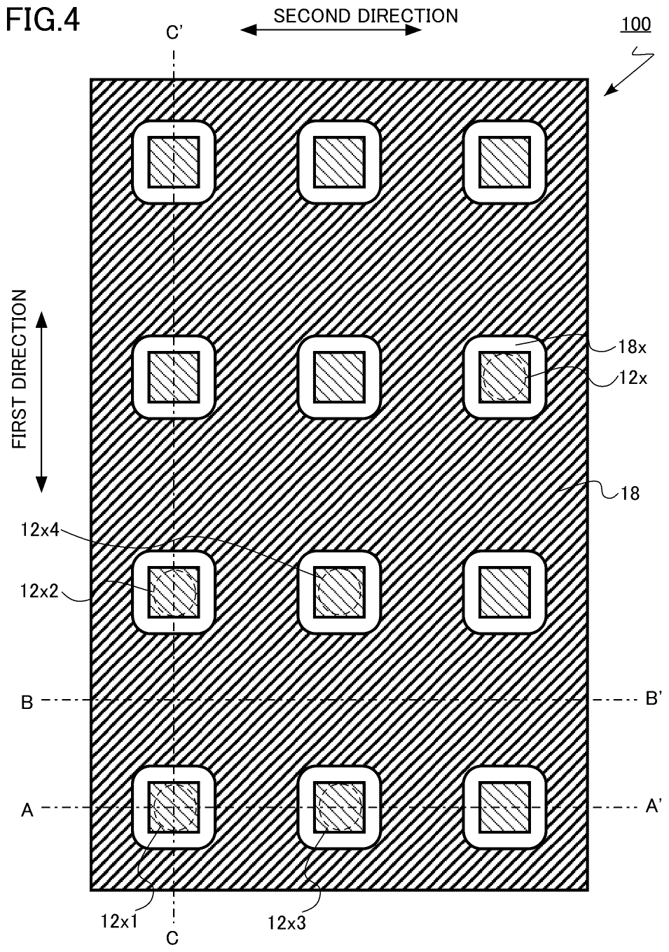

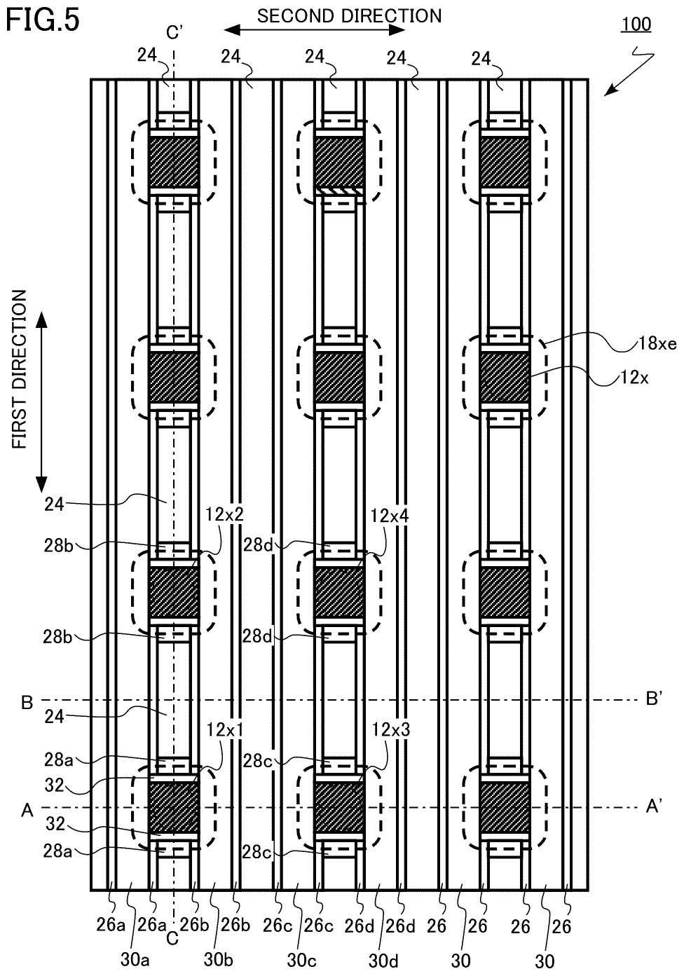

FIGS. 1, 2, and 3 are schematic cross-sectional views of the semiconductor device according to the first embodiment. FIGS. 4 and 5 are schematic top views of the semiconductor device according to the first embodiment. FIG. 4 is a schematic diagram showing the patterns of a gate electrode and a source electrode on the top surface side of a silicon carbide layer. FIG. 5 is a schematic diagram showing the patterns of a silicon carbide region and a source electrode on a first face of the silicon carbide layer. FIG. 1 is a cross-sectional view taken along the line AA′ of FIGS. 4 and 5. FIG. 2 is a cross-sectional view taken along the line BB′ of FIGS. 4 and 5. FIG. 3 is a cross-sectional view taken along the line CC′ of FIGS. 4 and 5.

The MOSFET 100 includes a silicon carbide layer 10, a source electrode 12 (first electrode), a drain electrode 14 (second electrode), a gate insulating layer 16, a gate electrode 18, and an interlayer insulating layer 20. The source electrode 12 includes a metal silicide layer 12s and a metal layer 12m. The source electrode 12 includes a contact portion 12x. The contact portion 12x includes a first contact portion 12x1 (first portion), a second contact portion 12x2 (second portion), a third contact portion 12x3 (third portion), and a fourth contact portion 12x4 (fourth portion).

The silicon carbide layer 10 includes an n⁺-type drain region 22, an n⁻-type drift region 24 (first silicon carbide region), a p-type base region 26, a p-type base connection region 28, an n-type source region 30, and an n⁺-type contact region 32. The p-type base region 26 includes a first base region 26a (second silicon carbide region), a second base region 26b (third silicon carbide region), a third base region 26c (fourth silicon carbide region), and a fourth base region 26d (tenth silicon carbide region). The p-type base connection region 28 includes a first base connection region 28a (eighth silicon carbide region), a second base connection region 28b (ninth silicon carbide region), a third base connection region 28c (twelfth silicon carbide region), and a fourth base connection region 28d (thirteenth silicon carbide region). The n-type source region 30 includes a first source region 30a (fifth silicon carbide region), a second source region 30b (sixth silicon carbide region), a third source region 30c (seventh silicon carbide region), and a fourth source region 30d (eleventh silicon carbide region).

The silicon carbide layer 10 is provided between the source electrode 12 and the drain electrode 14. The silicon carbide layer 10 is a single crystal SiC. The silicon carbide layer 10 is, for example, 4H—SiC.

The silicon carbide layer 10 has a first face (“F1” in FIG. 1) and a second face (“F2” in FIG. 1). The first face F1 is the surface of the silicon carbide layer. In addition, the second face F2 is the back surface of the silicon carbide layer. Hereinafter, the first face F1 may be referred to as a surface, and the second face F2 may be referred to as a back surface. The first face F1 is disposed on the source electrode 12 side of the silicon carbide layer 10. In addition, the second face F2 is disposed on the drain electrode 14 side of the silicon carbide layer 10. The first face F1 and the second face F2 face each other. Hereinafter, the “depth” means a depth in a direction toward the second face with the first face as a reference. In addition, “face” of the first face F1 and the second face F2 indicates, for example, an interface between a silicon carbide layer and an insulating film or between a silicon carbide layer and a metal.

The first direction and the second direction are parallel to the first face F1. The second direction is perpendicular to the first direction. The third direction is perpendicular to the first face F1.

The first face F1 is, for example, a face inclined by an angle equal to or more than 0° and equal to or less than 8° with respect to the (0001) face. In addition, the second face F2 is, for example, a face inclined by an angle equal to or more than 0° and equal to or less than 8° with respect to the (000-1) face. The (0001) face is referred to as a silicon face. The (000-1) face is referred to as a carbon face.

The n⁺-type drain region 22 is provided on the back surface side of the silicon carbide layer 10. The drain region 22 contains, for example, nitrogen (N) as an n-type impurity. The n-type impurity concentration in the drain region 22 is equal to or more than 1×10¹⁸ cm⁻³ and equal to or less than 1×10²¹ cm⁻³, for example.

The n⁻-type drift region 24 is provided between the drain region 22 and the first face F1. The n⁻-type drift region 24 is provided between the source electrode 12 and the drain electrode 14. The n⁻-type drift region 24 is provided between the gate electrode 18 and the drain electrode 14.

The n⁻-type drift region 24 is provided on the drain region 22. The drift region 24 contains, for example, nitrogen (N) as an n-type impurity. The n-type impurity concentration in the drift region 24 is lower than the n-type impurity concentration in the drain region 22. The n-type impurity concentration in the drift region 24 is equal to or more than 4×10¹⁴ cm⁻³ and equal to or less than 5×10¹⁷ cm⁻³, for example. The thickness of the drift region 24 is, for example, equal to or more than 3 μm and equal to or less than 150 μm.

A part of the drift region 24 is in contact with the first face F1.

The drift region 24 has a function of making a current flow when the MOSFET 100 is turned on.

The p-type base region 26 is provided between the drift region 24 and the first face F1. The base region 26 extends linearly in the first direction. The base region 26 is repeatedly arranged in the second direction. The drift region 24 is provided between two base regions 26 adjacent to each other in the second direction.

The base region 26 functions as a channel region of the MOSFET 100.

The first base region 26a is provided between the drift region 24 and the first face F1. The second base region 26b is provided between the drift region 24 and the first face F1. The third base region 26c is provided between the drift region 24 and the first face F1. The fourth base region 26d is provided between the drift region 24 and the first face F1.

The second base region 26b is spaced apart from the first base region 26a in the second direction. The third base region 26c is spaced apart from the second base region 26b in the second direction. The fourth base region 26d is spaced apart from the third base region 26c in the second direction.

The base region 26 contains, for example, aluminum (Al) as a p-type impurity. The p-type impurity concentration in the base region 26 is, for example, equal to or more than 5×10¹⁶ cm⁻³ and equal to or less than 5×10¹⁸ cm⁻³.

The length of the base region 26 in the second direction is, for example, equal to or more than 0.5 μm and equal to or less than 2 μm. The distance between two base regions adjacent to each other in the second direction is, for example, equal to or more than 0.5 μm and equal to or less than 2 μm.

The depth of the base region 26 is, for example, equal to or more than 1 μm and equal to or less than 2 μm.

The base region 26 is electrically connected to the source electrode 12. The base region 26 is fixed to the electric potential of the source electrode 12.

A part of the base region 26 is in contact with the first face F1. A part of the base region 26 faces the gate electrode 18. A part of the base region 26 serves as a channel region of the MOSFET 100. The gate insulating layer 16 is interposed between a part of the base region 26 and the gate electrode 18.

The p-type base connection region 28 is provided between the drift region 24 and the first face F1. The base connection region 28 is provided between two base regions 26 adjacent to each other in the second direction. The base connection region 28 is in contact with two base regions 26 adjacent to each other in the second direction.

The base connection region 28 is repeatedly arranged in the first direction. The drift region 24 is provided between two base connection regions 28 adjacent to each other in the first direction.

The first base connection region 28a is provided between the first base region 26a and the second base region 26b. The first base connection region 28a is in contact with the first base region 26a and the second base region 26b.

The second base connection region 28b is provided between the first base region 26a and the second base region 26b. The second base connection region 28b is in contact with the first base region 26a and the second base region 26b.

The second base connection region 28b is spaced apart from the first base connection region 28a in the first direction. The drift region 24 is provided between the second base connection region 28b and the first base connection region 28a.

The third base connection region 28c is provided between the third base region 26c and the fourth base region 26d. The third base connection region 28c is in contact with the third base region 26c and the fourth base region 26d.

The fourth base connection region 28d is provided between the third base region 26c and the fourth base region 26d. The fourth base connection region 28d is in contact with the third base region 26c and the fourth base region 26d.

The fourth base connection region 28d is spaced apart from the third base connection region 28c in the first direction. The drift region 24 is provided between the fourth base connection region 28d and the third base connection region 28c.

The third base connection region 28c is provided in the first direction with respect to the first base connection region 28a. The fourth base connection region 28d is provided in the first direction with respect to the second base connection region 28b.

Two base regions 26 between which the base connection region 28 is provided and two base regions 26 between which the base connection region 28 is not provided are repeatedly arranged in the second direction. For example, the base connection region 28 is not provided between the second base region 26b and the third base region 26c.

The base connection region 28 contains, for example, aluminum (Al) as a p-type impurity. The p-type impurity concentration in the base connection region 28 is, for example, equal to or more than 5×10¹⁶ cm⁻³ and equal to or less than 5×10¹⁸ cm⁻³.

For example, a portion having a high p-type impurity concentration may be provided in a portion of the base connection region 28 that is in contact with the source electrode. The p-type impurity concentration in the high p-type impurity concentration portion is, for example, equal to or more than 1×10¹⁹ cm⁻³ and equal to or less than 5×10²¹ cm⁻³.

The length of the base connection region 28 in the first direction is, for example, equal to or more than 2 μm and equal to or less than 5 μm. The distance in the first direction between two base connection regions 28 adjacent to each other in the first direction is, for example, equal to or more than 5 μm and equal to or less than 100 μm.

The distance in the first direction between two base connection regions 28 adjacent to each other in the first direction is, for example, equal to or more than 1.5 times and equal to or less than 50 times the length of the base connection regions 28 in the first direction.

The distance (D1 in FIG. 3) in the first direction between the first base connection region 28a and the second base connection region 28b is, for example, equal to or more than 1.5 times and equal to or less than 50 times the length (L1 in FIG. 3) of the first base connection region 28a in the first direction. In addition, the distance in the first direction between the third base connection region 28c and the fourth base connection region 28d is, for example, equal to or more than 1.5 times and equal to or less than 50 times the length of the third base connection region 28c in the first direction.

The distance in the first direction between two base connection regions 28 adjacent to each other in the first direction is, for example, equal to or more than two times and equal to or less than 50 times the distance in the second direction between two base regions 26 adjacent to each other in the second direction.

The distance (D1 in FIG. 3) in the first direction between the first base connection region 28a and the second base connection region 28b is, for example, equal to or more than two times and equal to or less than 50 times the distance (D2 in FIG. 2) in the second direction between the first base region 26a and the second base region 26b. In addition, the distance in the first direction between the third base connection region 28c and the fourth base connection region 28d is, for example, equal to or more than two times and equal to or less than 50 times the distance in the second direction between the third base region 26c and the fourth base region 26d.

The depth of the base connection region 28 is, for example, smaller than the depth of the base region 26. The depth of the base connection region 28 is, for example, equal to or more than 1/10 and equal to or less than ½ of the depth of the base region 26. The depth of the base connection region 28 is, for example, equal to or more than 0.5 μm and equal to or less than 1 μm. The depth of the base region 26 is, for example, larger than the depth of the base connection region 28. The depth of the base region 26 is, for example, equal to or more than two times and equal to or less than ten times the depth of the base connection region 28.

The base connection region 28 is electrically connected to the source electrode 12. The base connection region 28 is fixed to the electric potential of the source electrode 12.

A part of the base connection region 28 is in contact with, for example, the first face F1. The base connection region 28 does not function as a channel region of the MOSFET 100, for example.

The n⁺-type source region 30 is provided between the base region 26 and the first face F1. The source region 30 extends linearly in the first direction. The source region 30 is repeatedly arranged in the second direction. In the second direction, the base region 26 is provided between the source region 30 and the drift region 24.

The first source region 30a is provided between the first base region 26a and the first face F1. The second source region 30b is provided between the second base region 26b and the first face F1. The third source region 30c is provided between the third base region 26c and the first face F1. The fourth source region 30d is provided between the fourth base region 26d and the first face F1.

The source region 30 contains, for example, phosphorus (P) or nitrogen (N) as an n-type impurity. The n-type impurity concentration in the source region 30 is higher than the n-type impurity concentration in the drift region 24.

The n-type impurity concentration in the source region 30 is, for example, equal to or more than 1×10¹⁹ cm⁻³ and equal to or less than 5×10²¹ cm⁻³. The depth of the source region 30 is smaller than the depth of the base region 26. The depth of the source region 30 is, for example, equal to or more than 80 nm and equal to or less than 200 nm.

The source region 30 is electrically connected to the source electrode 12. The source region 30 is fixed to the electric potential of the source electrode 12.

The n⁺-type contact region 32 is provided between the base connection region 28 and the first face F1. The contact region 32 is provided between two source regions 30 adjacent to each other in the second direction. The contact region 32 is in contact with, for example, two source regions 30 adjacent to each other in the second direction.

For example, the base connection region 28 is provided between the contact region 32 and the drift region 24 in the first direction. The contact region 32 is in contact with, for example, the source electrode 12.

The contact region 32 contains, for example, phosphorus (P) or nitrogen (N) as an n-type impurity. The n-type impurity concentration in the contact region 32 is higher than the n-type impurity concentration in the drift region 24. The n-type impurity concentration in the contact region 32 is, for example, higher than the n-type impurity concentration in the source region 30.

The n-type impurity concentration in the contact region 32 is, for example, equal to or more than 1×10¹⁹ cm⁻³ and equal to or less than 5×10²¹ cm⁻³. The depth of the contact region 32 is smaller than the depth of the base region 26. The depth of the contact region 32 is, for example, equal to or more than 80 nm and equal to or less than 200 nm.

The contact region 32 is electrically connected to the source electrode 12. The contact region 32 is fixed to the electric potential of the source electrode 12.

The contact region 32 has a function of reducing the electrical resistance between the source electrode 12 and the source region 30, for example.

The source electrode 12 is provided on the first face F1 side of the silicon carbide layer 10. The source electrode 12 is in contact with the silicon carbide layer 10. The source electrode 12 is in contact with the base connection region 28. The source electrode 12 is in contact with, for example, the source region 30 and the contact region 32.

The source electrode 12 includes the contact portion 12x. The contact portion 12x is in contact with the base connection region 28. The first contact portion 12x1 is in contact with the first base connection region 28a. The second contact portion 12x2 is in contact with the second base connection region 28b. The third contact portion 12x3 is in contact with the third base connection region 28c. The fourth contact portion 12x4 is in contact with the fourth base connection region 28d.

For example, the interface between the contact portion 12x and the base connection region 28 is disposed closer to the second face F2 than the first face F1 in a third direction perpendicular to the first face F1. For example, the contact portion 12x is in contact with the source region 30 in the second direction. For example, the contact portion 12x is in contact with the contact region 32 in the first direction.

In the MOSFET 100, the contact portions 12x are adjacent to each other in the second direction. For example, the third contact portion 12x3 is disposed in the second direction of the first contact portion 12x1. In addition, for example, the fourth contact portion 12x4 is disposed in the second direction of the second contact portion 12x2.

The source electrode 12 includes the metal silicide layer 12s and the metal layer 12m. The metal silicide layer 12s is provided between the silicon carbide layer 10 and the metal layer 12m. In addition, it is also possible to omit the metal silicide layer 12s from the source electrode 12.

The metal silicide layer 12s is in contact with, for example, the base contact region 28. The metal silicide layer 12s is in contact with, for example, the source region 30. The metal silicide layer 12s is in contact with, for example, the contact region 32.

The metal silicide layer 12s contains, for example, nickel (Ni), titanium (Ti), or cobalt (Co). The metal silicide layer 12s is, for example, a nickel silicide layer, a titanium silicide layer, or a cobalt silicide layer.

The metal layer 12m contains metal. The metal layer 12m has, for example, a stacked structure of a barrier metal film and a metal film.

The barrier metal film contains, for example, titanium (Ti), tungsten (W), or tantalum (Ta). The barrier metal film is, for example, a titanium film, a titanium nitride film, a tungsten nitride film, or a tantalum nitride film.

The metal film contains, for example, aluminum (Al). The metal film is, for example, an aluminum film.

The contact portion 12x includes the metal silicide layer 12s. Since the contact portion 12x includes the metal silicide layer 12s, for example, an ohmic contact is formed between the source electrode 12 and the base connection region 28 and between the source electrode 12 and the source region 30.

The gate electrode 18 is provided on the first face F1 side of the silicon carbide layer 10. The gate electrode 18 faces the drift region 24, the base region 26, and the source region 30 on the first face F1.

The gate electrode 18 is provided between the source electrode 12 and the silicon carbide layer 10. As shown in FIG. 4, the gate electrode 18 has an opening 18x. In FIG. 5, an end portion 18xe of the opening 18x of the gate electrode 18 is indicated by a dotted line.

The contact portion 12x of the source electrode 12 is provided in the opening 18x of the gate electrode 18. The gate electrode 18 surrounds the contact portion 12x in a plane parallel to the first face F1.

The base connection region 28 is present on the first face F1 in the third direction of an end portion in the first direction of the gate electrode 18 between two contact portions 12x adjacent to each other in the first direction. In other words, the end portion in the first direction of the gate electrode 18 between two contact portions 12x adjacent to each other in the first direction is located directly above the base connection region 28 of the first face F1. An end portion in the first direction of the gate electrode 18 between two contact portions 12x adjacent to each other in the first direction overlaps the base connection region 28 in the first direction.

For example, the first base connection region 28a or the second base connection region 28b is present on the first face F1 in the third direction of an end portion in the first direction of the gate electrode 18 between the first contact portion 12x1 and the second contact portion 12x2. For example, the first base connection region 28a is present on the first face F1 in the third direction of a first end portion (E1 in FIG. 3) on the first contact portion 12x1 side in the first direction of the gate electrode 18 between the first contact portion 12x1 and the second contact portion 12x2. In addition, for example, the second base connection region 28b is present on the first face F1 in the third direction of a second end portion (E2 in FIG. 3) on the second contact portion 12x2 side in the first direction of the gate electrode 18 between the first contact portion 12x1 and the second contact portion 12x2.

For example, in the first direction of the first contact portion 12x1, the n⁺-type contact region 32 and the first end portion E1 of the gate electrode are spaced apart from each other, and the first base connection region 28a does not function as a channel region of the MOSFET 100. In addition, in the first direction of the second contact portion 12x2, the n⁺-type contact region 32 and the second end portion E2 of the gate electrode are spaced apart from each other, and the second base connection region 28b does not function as a channel region of the MOSFET 100.

The gate electrode 18 is a conductive layer. The gate electrode 18 is, for example, polycrystalline silicon containing p-type impurities or n-type impurities.

The gate insulating layer 16 is provided between the drift region 24, the base region 26, and the source region 30 and the gate electrode 18.

The gate insulating layer 16 contains, for example, silicon oxide. The gate insulating layer 16 includes, for example, a silicon oxide layer. For example, an insulating material with a high dielectric constant can be applied to the gate insulating layer 16. In addition, for example, a stacked structure of a silicon oxide layer and an insulating material with a high dielectric constant can be applied to the gate insulating layer 16.

The thickness of the gate insulating layer 16 is, for example, equal to or more than 30 nm and equal to or less than 100 nm.

The interlayer insulating layer 20 is provided on the gate electrode 18. The interlayer insulating layer 20 is provided between the gate electrode 18 and the source electrode 12.

The interlayer insulating layer 20 electrically separates the gate electrode 18 and the source electrode 12 from each other. The interlayer insulating layer 20 contains, for example, silicon oxide. The interlayer insulating layer 20 is, for example, a silicon oxide layer.

The drain electrode 14 is provided on the second face F2 side of the silicon carbide layer 10. The drain electrode 14 is provided on the second face F2 of the silicon carbide layer 10. The drain electrode 14 is in contact with the second face F2.

The drain electrode 14 contains, for example, a metal or a metal semiconductor compound. The drain electrode 14 includes, for example, a nickel silicide layer, a titanium layer, a nickel layer, a silver layer, or a gold layer.

The drain electrode 14 is electrically connected to the drain region 22. The drain electrode 14 is in contact with, for example, the drain region 22.

Next, the function and effect of the MOSFET 100 according to the first embodiment will be described.

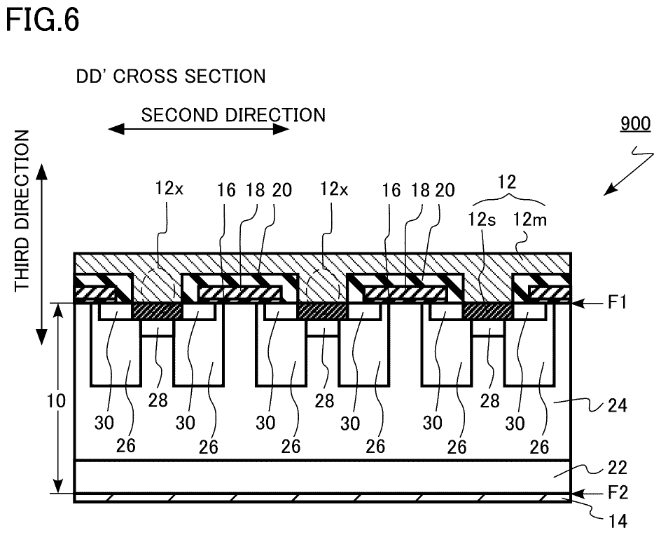

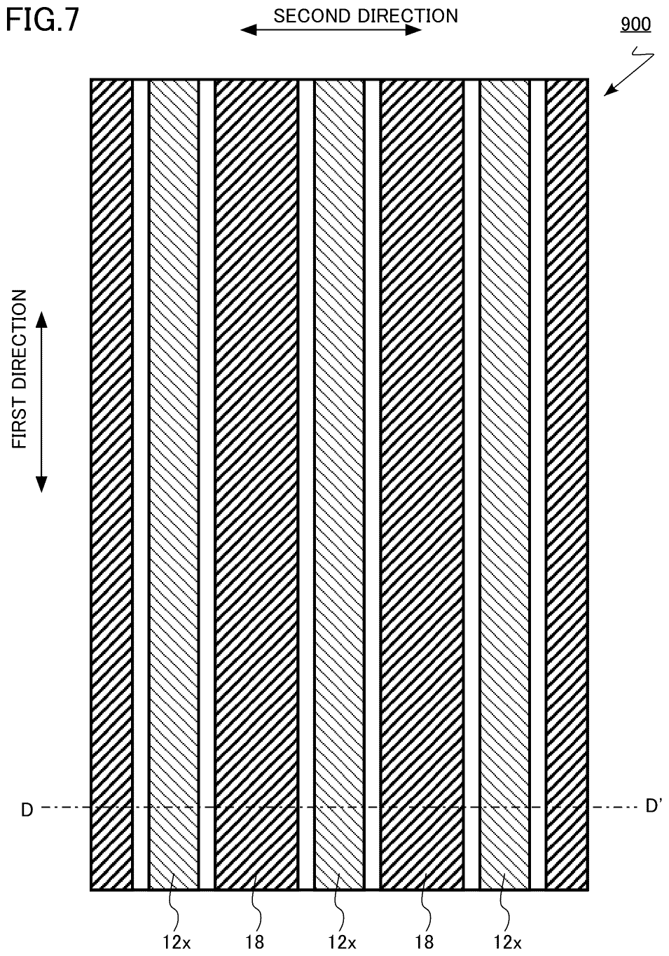

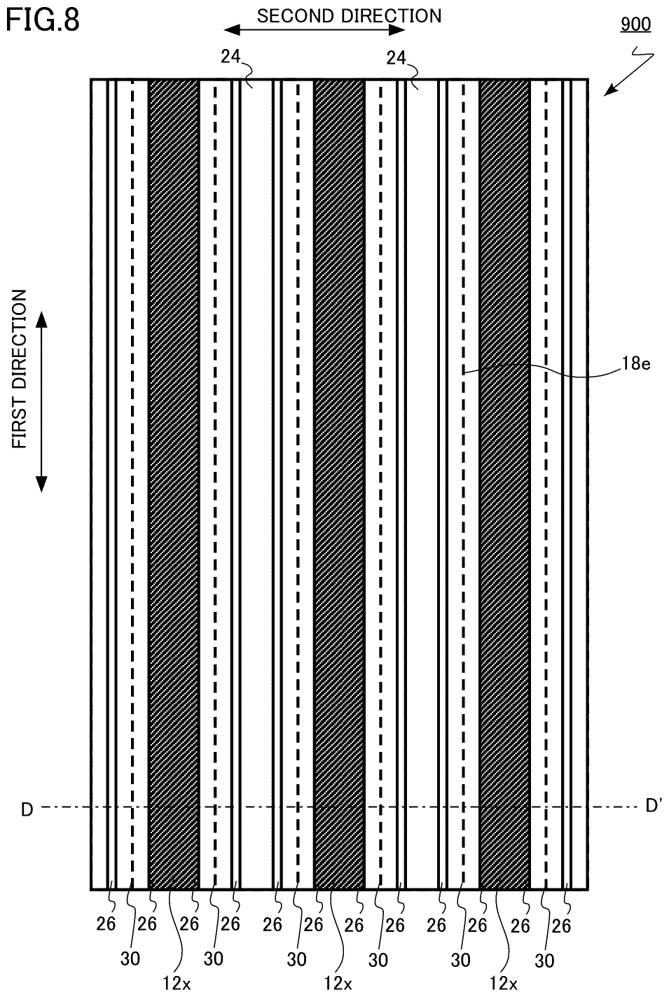

FIG. 6 is a schematic cross-sectional view of a semiconductor device according to a comparative example. FIGS. 7 and 8 are schematic top views of the semiconductor device according to the comparative example. FIG. 7 is a schematic diagram showing the patterns of a gate electrode and a source electrode on the top surface side of a silicon carbide layer. FIG. 8 is a schematic diagram showing the patterns of a silicon carbide region and a source electrode on the first face of a silicon carbide layer. FIG. 6 is a cross-sectional view taken along the line DD′ of FIGS. 7 and 8.

FIG. 6 is a diagram corresponding to FIG. 1 of the first embodiment. FIG. 7 is a diagram corresponding to FIG. 4 in the first embodiment. FIG. 8 is a diagram corresponding to FIG. 5 in the first embodiment.

The semiconductor device according to the comparative example is a MOSFET 900. The MOSFET 900 has the same patterns of the base region 26 and the source region 30 as the MOSFET 100 according to the first embodiment. The MOSFET 900 is different from the MOSFET 100 according to the first embodiment in that the pattern of the gate electrode 18 has a striped shape that extends in the first direction and is repeatedly arranged in the second direction. In addition, the MOSFET 900 is different from the MOSFET 100 according to the first embodiment in that the contact portion 12x of the source electrode 12 has a striped shape that extends in the first direction and is repeatedly arranged in the second direction. In FIG. 8, an end portion 18e of the gate electrode 18 is indicated by the dotted line.

In the MOSFET 900, only the base region 26 facing the gate electrode 18 with a striped shape functions as a channel region. On the other hand, in the MOSFET 100 according to the first embodiment, the contact portion 12x of the source electrode 12 is divided in the first direction. Then, the gate electrode 18 is also provided between the contact portions 12x adjacent to each other in the first direction. Therefore, in the MOSFET 100, in addition to the channel region of the MOSFET 900, the base region 26 facing the gate electrode 18 also functions as a channel region between the contact portions 12x adjacent to each other in the first direction.

Therefore, in the MOSFET 100, since a channel region increases compared with the MOSFET 900, the effective channel width of the MOSFET increases. As a result, the on-resistance of the MOSFET 100 is reduced.

From the viewpoint of increasing the effective channel width to reduce the on-resistance of the MOSFET 100, the distance in the first direction between two base connection regions 28 adjacent to each other in the first direction is preferably equal to or more than 1.5 times, more preferably equal to or more than 2 times, and even more preferably equal to or more than 3 times the length of the base connection region 28 in the first direction.

In addition, the depth of the base connection region 28 is preferably smaller than the depth of the base region 26. In other words, the depth of the base region 26 is preferably larger than the depth of the base connection region 28. By increasing the depth of the base region 26, the short-circuit resistance of the MOSFET 100 is improved. In addition, by making the depth of the base connection region 28 small, the on-current flowing from the channel region disposed in the first direction of the contact portion 12x to the drift region 24 is more likely to diffuse in the drift region 24 below the base connection region 28 because the base connection region 28 is shallow. As a result, the on-resistance of the MOSFET 100 is reduced.

In addition, it is preferable that the base connection region 28 provided in the first direction of the contact portion 12x does not function as a channel region of the MOSFET 100. This is because a region of the contact portion 12x consumed in the first direction is increased by providing a structure for the base connection region 28 to function as a channel region, and as a result, it becomes difficult to increase the effective channel width of the MOSFET 100.

Therefore, it is preferable that the base connection region 28 is present on the first face F1 in the third direction of the end portion in the first direction of the gate electrode 18 between two contact portions 12x adjacent to each other in the first direction. In other words, it is preferable that the end portion in the first direction of the gate electrode 18 between two contact portions 12x adjacent to each other in the first direction is located directly above the base connection region 28 of the first face F1.

In addition, it is assumed that the base connection region 28 provided in the first direction of the contact portion 12x is made to function as a channel region of the MOSFET 100 and that the width of the base connection region 28 in the second direction is increased to increase the on-current in this region. In this case, the repetition period of the gate electrode 18 in the second direction is increased, which is contrary to the increase in the on-current per unit area. In addition, increasing the width of the base connection region 28 in the second direction necessarily increases the distance between the base regions 26 in the second direction. If the distance between the base regions 26 in the second direction increases, the electric field relaxation effect in a portion between the base regions 26 of the MOSFET 100 or the short-circuit current suppression effect by the portion between the base regions 26 is no longer obtained. As a result, the characteristics of the MOSFET 100 deteriorate.

In addition, when the drift region 24 is present on the first face F1 in the third direction of the end portion of the gate electrode 18 in the first direction, the electric field strength applied to the gate insulating layer 16 between the end portion of the gate electrode 18 and the drift region 24 increases. This may lower the reliability of the gate insulating layer 16. Also from the viewpoint of improving the reliability of the gate insulating layer 16, it is preferable that the end portion in the first direction of the gate electrode 18 between two contact portions 12x adjacent to each other in the first direction is located directly above the base connection region 28 of the first face F1.

As described above, according to the MOSFET 100 according to the first embodiment, since the effective channel width increases, a MOSFET with a reduced on-resistance is realized.

### First Modification Example

A semiconductor device according to a first modification example of the first embodiment is different from the semiconductor device according to the first embodiment in that the depths of the second silicon carbide region and the third silicon carbide region are substantially the same as the depths of the eighth silicon carbide region and the ninth silicon carbide region.

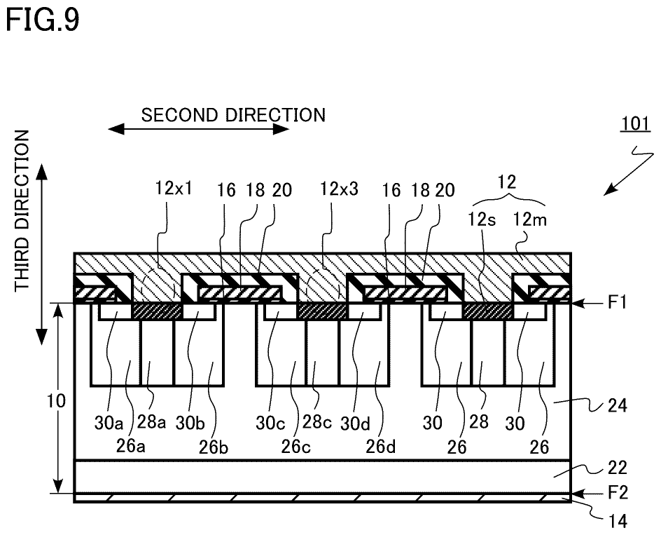

FIG. 9 is a schematic cross-sectional view of the semiconductor device according to the first modification example of the first embodiment. FIG. 9 is a diagram corresponding to FIG. 1 in the first embodiment.

A MOSFET 101 according to the first modification example of the first embodiment is different from the MOSFET 100 according to the first embodiment in that the depth of the base connection region 28 is substantially the same as the depth of the base region 26.

According to the MOSFET 101 according to the first modification example of the first embodiment, similarly to the MOSFET 100, the effective channel width increases, and as a result, a MOSFET with a reduced on-resistance is realized.

### Second Modification Example

A semiconductor device according to a second modification example of the first embodiment is different from the semiconductor device according to the first embodiment in that the interface between the contact portion 12x and the base connection region 28 is on the first face F1.

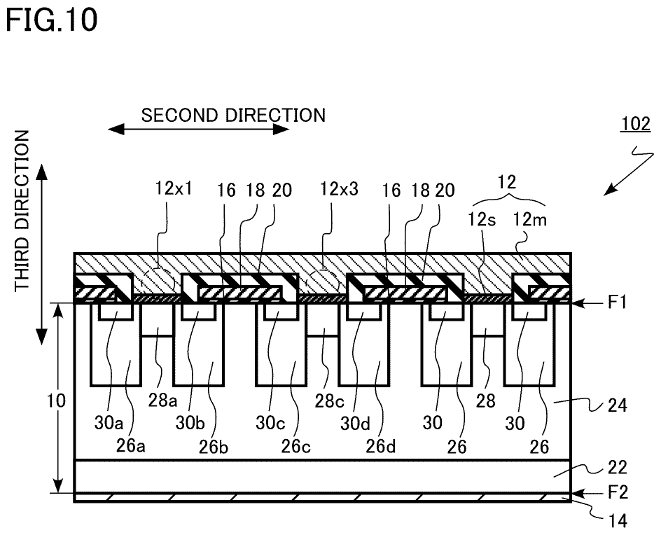

FIG. 10 is a schematic cross-sectional view of the semiconductor device according to the second modification example of the first embodiment. FIG. 10 is a diagram corresponding to FIG. 1 in the first embodiment.

In a MOSFET 102 according to the second modification example of the first embodiment, the interface between the contact portion 12x and the base connection region 28 is on the first face F1.

According to the MOSFET 102 according to the second modification example of the first embodiment, similarly to the MOSFET 100, the effective channel width increases, and as a result, a MOSFET with a reduced on-resistance is realized.

As described above, according to the first embodiment and its modification examples, since the effective channel width increases, a MOSFET with a reduced on-resistance is realized.

### Second Embodiment

A semiconductor device according to a second embodiment is different from the semiconductor device according to the first embodiment in that the position of the third portion in the first direction is between the position of the first portion in the first direction and the position of the second portion in the first direction. Hereinafter, the description of a part of the content overlapping the first embodiment may be omitted.

The semiconductor device according to the first embodiment is a planar gate vertical MOSFET 200 using silicon carbide.

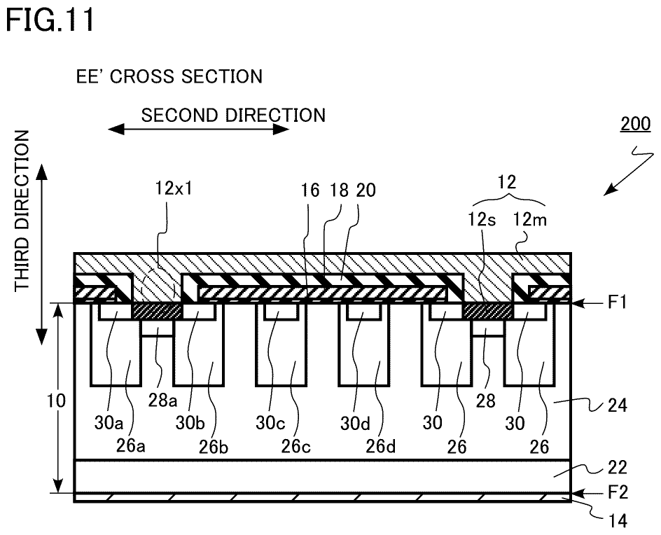

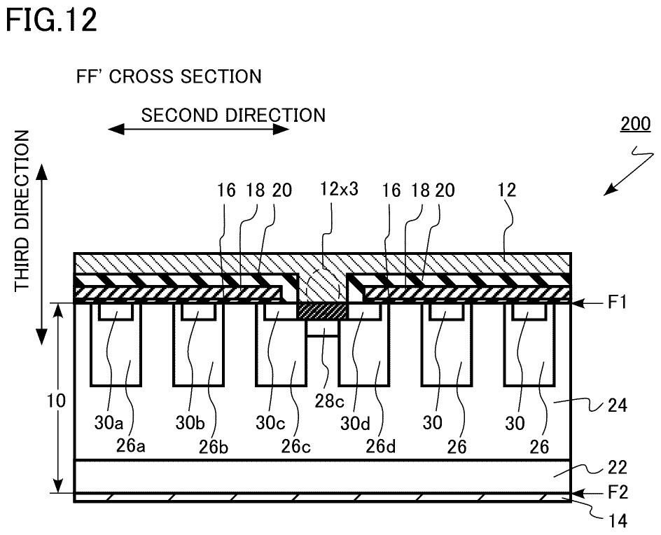

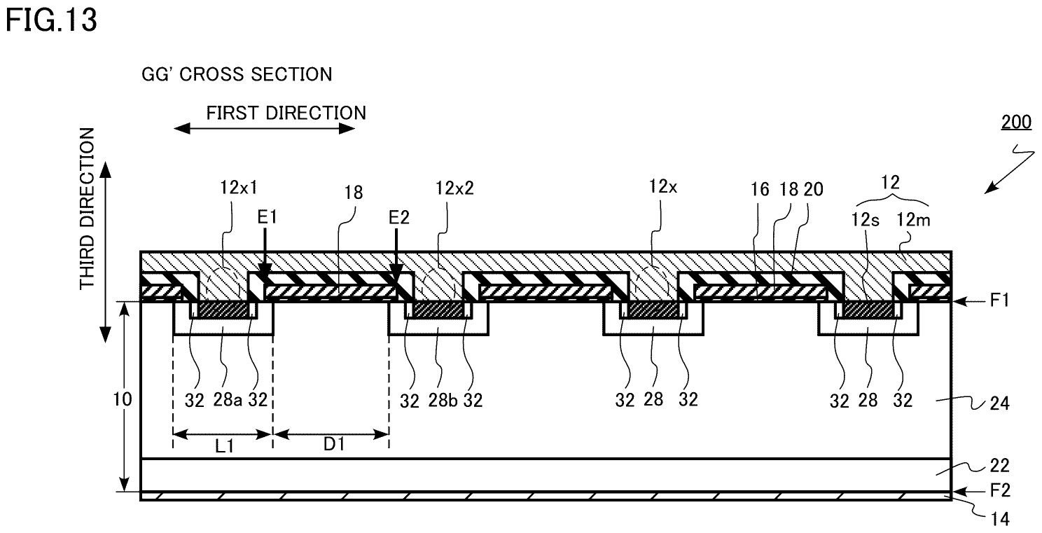

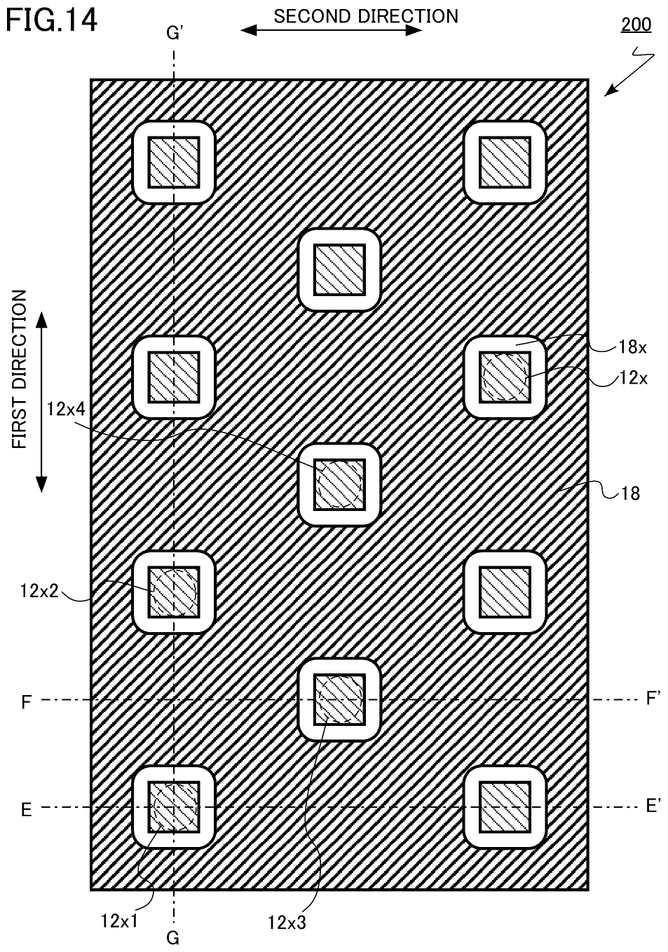

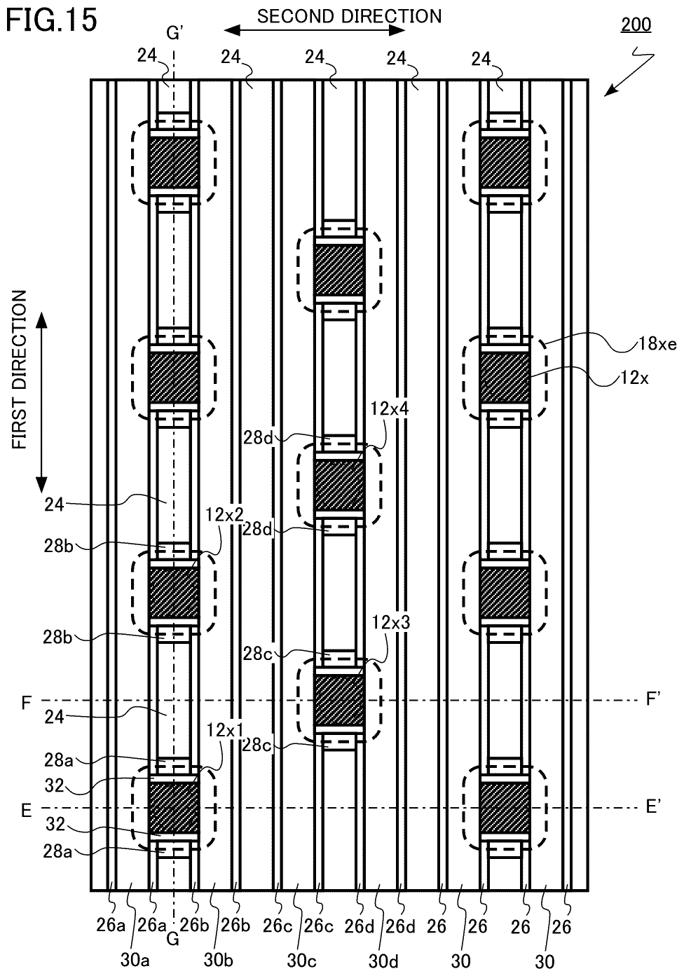

FIGS. 11, 12, and 13 are schematic cross-sectional views of the semiconductor device according to the second embodiment. FIGS. 14 and 15 are schematic top views of the semiconductor device according to the second embodiment. FIG. 14 is a schematic diagram showing the patterns of a gate electrode and a source electrode on the top surface side of a silicon carbide layer. FIG. 15 is a schematic diagram showing the patterns of a silicon carbide region and a source electrode on the first face of the silicon carbide layer. FIG. 11 is a cross-sectional view taken along the line EE′ of FIGS. 14 and 15. FIG. 12 is a cross-sectional view taken along the line FF′ of FIGS. 14 and 15. FIG. 13 is a cross-sectional view taken along the line GG′ of FIGS. 14 and 15.

In a MOSFET 200, contact portions 12x are arranged side by side in the first direction. A row of contact portions 12x aligned in the first direction is shifted in the first direction by a half period from a row of contact portions 12x aligned in the first direction that is adjacent in the second direction. In other words, the contact portions 12x are arranged in a checkerboard pattern on the first face F1.

For example, the position of the third contact portion 12x3 in the first direction is between the position of the first contact portion 12x1 in the first direction and the position of the second contact portion 12x2 in the first direction. For example, the position of the third contact portion 12x3 in the first direction is an intermediate position between the position of the first contact portion 12x1 in the first direction and the position of the second contact portion 12x2 in the first direction.

According to the MOSFET 200 according to the second embodiment, similarly to the MOSFET 100 according to the first embodiment, the effective channel width increases, and as a result, a MOSFET with a reduced on-resistance is realized.

In addition, since the openings 18x of the gate electrode 18 are arranged in a checkerboard pattern, the distance between two openings 18x is larger than that in the MOSFET 100 according to the first embodiment. This makes it easier to pattern the gate electrode 18.

In addition, since the contact portions 12x of the source electrode 12 are arranged in a checkerboard pattern, the source of heat generation when a short circuit occurs in the MOSFET 200 is dispersed more than in the MOSFET 100, for example. Therefore, the short-circuit resistance of the MOSFET 200 is improved.

In addition, the row of contact portions 12x aligned in the first direction may be shifted, for example, by ⅓ period in the first direction or ¼ period in the first direction, so as to be repeatedly arranged in the second direction.

As described above, according to the second embodiment, since the effective channel width increases, a MOSFET with a reduced on-resistance is realized.

### Third Embodiment

A semiconductor device according to a third embodiment is different from the semiconductor device according to the first embodiment in that the silicon carbide layer further includes: a tenth silicon carbide region of the second conductive type provided between the first silicon carbide region and the first face, provided between the third silicon carbide region and the fourth silicon carbide region, and in contact with the third silicon carbide region and the fourth silicon carbide region; and an eleventh silicon carbide region of the second conductive type provided between the first silicon carbide region and the first face, provided between the third silicon carbide region and the fourth silicon carbide region, in contact with the third silicon carbide region and the fourth silicon carbide region, and spaced apart from the tenth silicon carbide region in the first direction, the first electrode further includes a third portion in contact with the tenth silicon carbide region and a fourth portion in contact with the eleventh silicon carbide region, the gate electrode surrounds the third portion and the fourth portion, and a position of the third portion in the first direction is between a position of the first portion in the first direction and a position of the second portion in the first direction. Hereinafter, the description of a part of the content overlapping the first embodiment may be omitted.

The semiconductor device according to the third embodiment is a planar gate vertical MOSFET 300 using silicon carbide.

Hereinafter, a case where the first conductive type is n-type and the second conductive type is p-type will be described as an example. A MOSFET 300 is a vertical n-channel MOSFET having electrons as carriers.

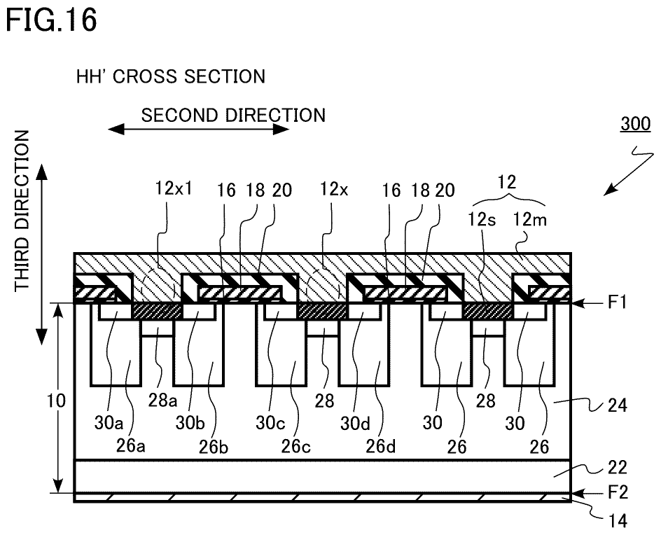

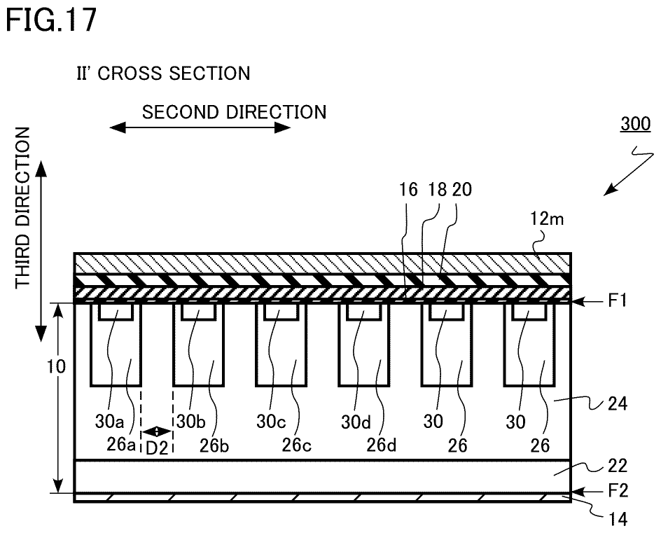

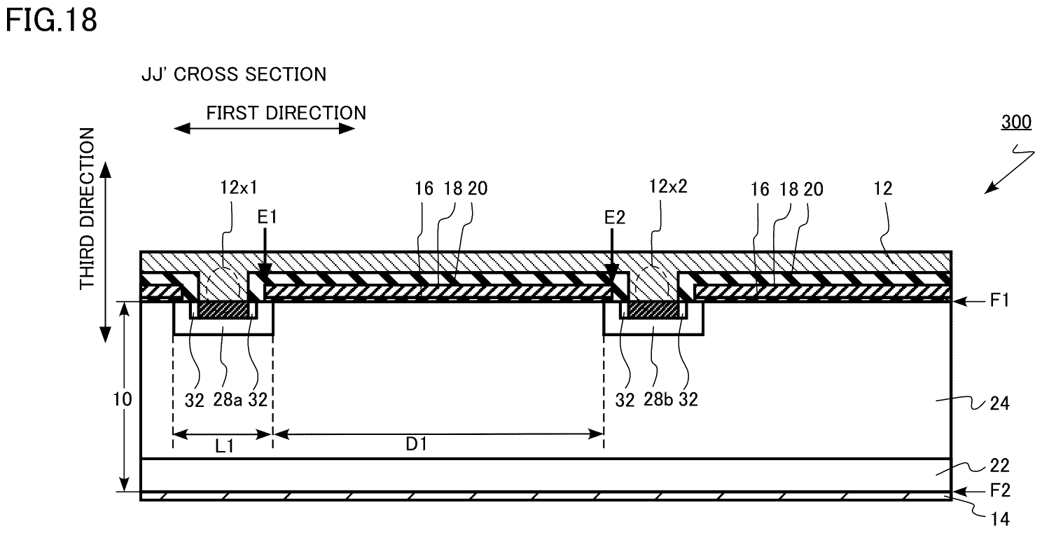

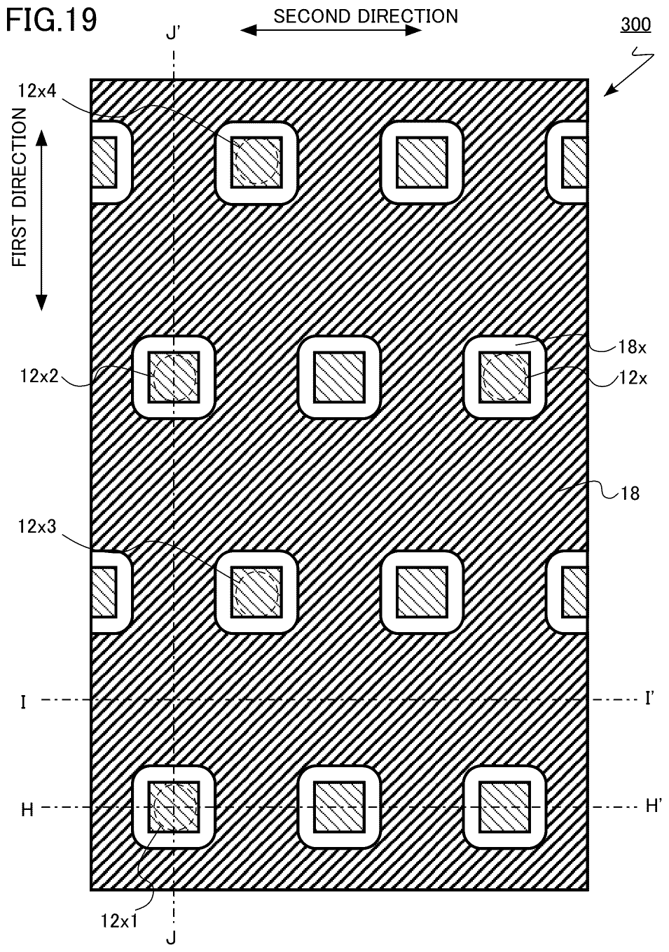

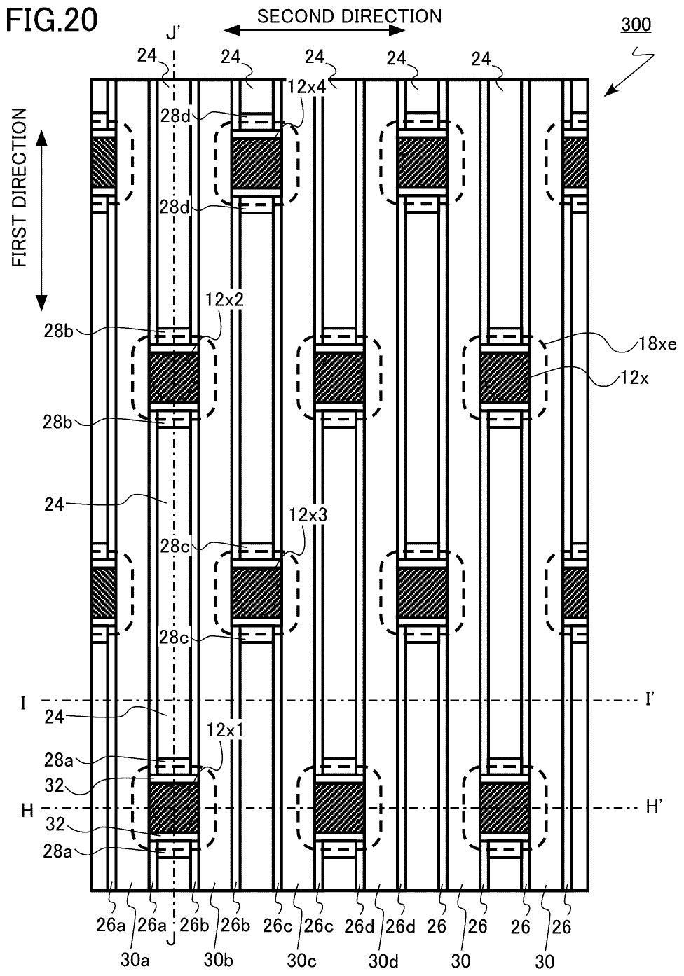

FIGS. 16, 17, and 18 are schematic cross-sectional views of the semiconductor device according to the third embodiment. FIGS. 19 and 20 are schematic top views of the semiconductor device according to the third embodiment. FIG. 16 is a schematic diagram showing the patterns of a gate electrode and a source electrode on the top surface side of the silicon carbide layer. FIG. 17 is a schematic diagram showing the patterns of a silicon carbide region and a source electrode on the first face of the silicon carbide layer. FIG. 16 is a cross-sectional view taken along the line HH′ of FIGS. 19 and 20. FIG. 17 is a cross-sectional view taken along the line II′ of FIGS. 19 and 20. FIG. 18 is a cross-sectional view taken along the line JJ′ of FIGS. 19 and 20.

The MOSFET 300 includes a silicon carbide layer 10, a source electrode 12 (first electrode), a drain electrode 14 (second electrode), a gate insulating layer 16, a gate electrode 18, and an interlayer insulating layer 20. The source electrode 12 includes a metal silicide layer 12s and a metal layer 12m. The source electrode 12 includes a contact portion 12x. The contact portion 12x includes a first contact portion 12x1 (first portion), a second contact portion 12x2 (second portion), a third contact portion 12x3 (third portion), and a fourth contact portion 12x4 (fourth portion).

The silicon carbide layer 10 includes an n⁺-type drain region 22, an n⁻-type drift region 24 (first silicon carbide region), a p-type base region 26, a p-type base connection region 28, an n-type source region 30, and an n⁺-type contact region 32. The p-type base region 26 includes a first base region 26a (second silicon carbide region), a second base region 26b (third silicon carbide region), a third base region 26c (fourth silicon carbide region), and a fourth base region 26d. The p-type base connection region 28 includes a first base connection region 28a (eighth silicon carbide region), a second base connection region 28b (ninth silicon carbide region), a third base connection region 28c (tenth silicon carbide region), and a fourth base connection region 28d (eleventh silicon carbide region). The n-type source region 30 includes a first source region 30a (fifth silicon carbide region), a second source region 30b (sixth silicon carbide region), a third source region 30c (seventh silicon carbide region), and a fourth source region 30d.

The p-type base connection region 28 is provided between the drift region 24 and the first face F1. The base connection region 28 is provided between two base regions 26 adjacent to each other in the second direction. The base connection region 28 is in contact with two base regions 26 adjacent to each other in the second direction.

The base connection region 28 is repeatedly arranged in the first direction. The drift region 24 is provided between two base connection regions 28 adjacent to each other in the first direction.

The first base connection region 28a is provided between the first base region 26a and the second base region 26b. The first base connection region 28a is in contact with the first base region 26a and the second base region 26b.

The second base connection region 28b is provided between the first base region 26a and the second base region 26b. The second base connection region 28b is in contact with the first base region 26a and the second base region 26b.

The second base connection region 28b is spaced apart from the first base connection region 28a in the first direction. The drift region 24 is provided between the second base connection region 28b and the first base connection region 28a.

The third base connection region 28c is provided between the second base region 26b and the third base region 26c. The third base connection region 28c is in contact with the second base region 26b and the third base region 26c.

The fourth base connection region 28d is provided between the second base region 26b and the third base region 26c. The fourth base connection region 28d is in contact with the second base region 26b and the third base region 26c.

The fourth base connection region 28d is spaced apart from the third base connection region 28c in the first direction. The drift region 24 is provided between the fourth base connection region 28d and the third base connection region 28c.

Two base regions 26 between which the base connection region 28 is provided are repeatedly arranged in the second direction. The base connection region 28 is provided on both sides of one base region 26 in the second direction so as to be in contact with the base region 26. For example, the base connection region 28 is provided between every two base regions 26 adjacent to each other in the second direction.

In the MOSFET 300, the contact portions 12x are arranged side by side in the first direction. A row of contact portions 12x aligned in the first direction is shifted in the first direction by a half period from a row of contact portions 12x aligned in the first direction that is adjacent in the second direction. In other words, the contact portions 12x are arranged in a checkerboard pattern on the first face F1.

For example, the position of the third contact portion 12x3 in the first direction is between the position of the first contact portion 12x1 in the first direction and the position of the second contact portion 12x2 in the first direction. For example, the position of the third contact portion 12x3 in the first direction is an intermediate position between the position of the first contact portion 12x1 in the first direction and the position of the second contact portion 12x2 in the first direction.

The distance in the first direction between two base connection regions 28 adjacent to each other in the first direction is, for example, equal to or more than 3 times and equal to or less than 100 times the length of the base connection regions 28 in the first direction.

The distance (D1 in FIG. 18) in the first direction between the first base connection region 28a and the second base connection region 28b is, for example, equal to or more than 3 times and equal to or less than 100 times the length (L1 in FIG. 18) of the first base connection region 28a in the first direction. In addition, the distance between the third base connection region 28c and the fourth base connection region 28d in the first direction is, for example, equal to or more than 3 times and equal to or less than 100 times the length of the third base connection region 28c in the first direction.

The distance in the first direction between two base connection regions 28 adjacent to each other in the first direction is, for example, equal to or more than 4 times and equal to or less than 100 times the distance in the second direction between two base regions 26 adjacent to each other in the second direction.

The distance (D1 in FIG. 18) in the first direction between the first base connection region 28a and the second base connection region 28b is, for example, equal to or more than 4 times and equal to or less than 100 times the distance (D2 in FIG. 17) between the first base region 26a and the second base region 26b in the second direction. In addition, the distance between the third base connection region 28c and the fourth base connection region 28d in the first direction is, for example, equal to or more than 4 times and equal to or less than 100 times the distance between the third base region 26c and the fourth base region 26d in the second direction.

The base connection region 28 is present on the first face F1 in the third direction of an end portion in the first direction of the gate electrode 18 between two contact portions 12x adjacent to each other in the first direction. In other words, the end portion in the first direction of the gate electrode 18 between two contact portions 12x adjacent to each other in the first direction is located directly above the base connection region 28 of the first face F1. The end portion in the first direction of the gate electrode 18 between two contact portions 12x adjacent to each other in the first direction overlaps the base connection region 28 in the first direction.

For example, the first base connection region 28a or the second base connection region 28b is present on the first face F1 in the third direction of an end portion in the first direction of the gate electrode 18 between the first contact portion 12x1 and the second contact portion 12x2. For example, the first base connection region 28a is present on the first face F1 in the third direction of a first end portion (E1 in FIG. 18) of the gate electrode 18 between the first contact portion 12x1 and the second contact portion 12x2 on the first contact portion 12x1 side in the first direction. In addition, for example, the second base connection region 28b is present on the first face F1 in the third direction of a second end portion (E2 in FIG. 18) of the gate electrode 18 between the first contact portion 12x1 and the second contact portion 12x2 on the second contact portion 12x2 side in the first direction.

For example, in the first direction of the first contact portion 12x1, the n⁺-type contact region 32 and the first end portion E1 of the gate electrode are spaced apart from each other, and the first base connection region 28a does not function as a channel region of the MOSFET 100. In addition, in the first direction of the second contact portion 12x2, the n⁺-type contact region 32 and the second end portion E2 of the gate electrode are spaced apart from each other, and the second base connection region 28b does not function as a channel region of the MOSFET 300.

It is preferable that the base connection region 28 provided in the first direction of the contact portion 12x does not function as a channel region of the MOSFET 100. This is because a region of the contact portion 12x consumed in the first direction is increased by providing a structure for the base connection region 28 to function as a channel region, and as a result, it becomes difficult to increase the effective channel width of the MOSFET 300.

According to the MOSFET 300 according to the third embodiment, similarly to the MOSFET 100 according to the first embodiment, the effective channel width increases, and as a result, a MOSFET with a reduced on-resistance is realized.

In addition, since the openings 18x of the gate electrode 18 are arranged in a checkerboard pattern, the distance between two openings 18x is larger than that in the MOSFET 100 according to the first embodiment. This makes it easier to pattern the gate electrode 18.

In addition, since the contact portions 12x of the source electrode 12 are arranged in a checkerboard pattern, the source of heat generation when a short circuit occurs in the MOSFET 300 is dispersed more than in the MOSFET 100, for example. Therefore, the short-circuit resistance of the MOSFET 300 is improved.

In addition, the row of contact portions 12x aligned in the first direction may be shifted, for example, by ⅓ period in the first direction or ¼ period in the first direction, so as to be repeatedly arranged in the second direction.

As described above, according to the third embodiment, since the effective channel width increases, a MOSFET with a reduced on-resistance is realized.

In the first to third embodiments, the case of 4H—SiC has been described as an example of the crystal structure of SiC. However, embodiments can also be applied to devices using SiC having other crystal structures, such as 6H—SiC and 3C—SiC. In addition, a face other than the (0001) face can also be applied as the surface of the silicon carbide layer 10.

In the first to third embodiments, the case where the first conductive type is n-type and the second conductive type is p-type has been described as an example. However, the first conductive type can be p-type and the second conductive type can be n-type.

In the first to third embodiments, aluminum (Al) is exemplified as a p-type impurity, but boron (B) can also be used. In addition, although nitrogen (N) and phosphorus (P) are exemplified as n-type impurities, arsenic (As), antimony (Sb), and the like can also be applied.

While certain embodiments have been described, these embodiments have been presented by way of example only, and are not intended to limit the scope of the inventions. Indeed, the semiconductor device described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device, comprising:
a silicon carbide layer having a first face and a second face opposite to the first face and including:
a first silicon carbide region of a first conductive type;
a second silicon carbide region of a second conductive type provided between the first silicon carbide region and the first face and extending in a first direction parallel to the first face;
a third silicon carbide region of a second conductive type provided between the first silicon carbide region and the first face, extending in the first direction, and spaced apart from the second silicon carbide region in a second direction parallel to the first face and perpendicular to the first direction;
a fourth silicon carbide region of the second conductive type provided between the first silicon carbide region and the first face, extending in the first direction, and spaced apart from the third silicon carbide region in the second direction;
a fifth silicon carbide region of the first conductive type provided between the second silicon carbide region and the first face and extending in the first direction;
a sixth silicon carbide region of the first conductive type provided between the third silicon carbide region and the first face and extending in the first direction;
a seventh silicon carbide region of the first conductive type provided between the fourth silicon carbide region and the first face and extending in the first direction;
an eighth silicon carbide region of the second conductive type provided between the first silicon carbide region and the first face, provided between the second silicon carbide region and the third silicon carbide region, and in contact with the second silicon carbide region and the third silicon carbide region; and
a ninth silicon carbide region of the second conductive type provided between the first silicon carbide region and the first face, provided between the second silicon carbide region and the third silicon carbide region, in contact with the second silicon carbide region and the third silicon carbide region, and spaced apart from the eighth silicon carbide region in the first direction;
a first electrode including a first portion in contact with the eighth silicon carbide region and a second portion in contact with the ninth silicon carbide region, electrically connected to the fifth silicon carbide region, the sixth silicon carbide region, and the seventh silicon carbide region, and provided on the first face side of the silicon carbide layer;
a gate electrode facing the first silicon carbide region, the second silicon carbide region, the third silicon carbide region, the fourth silicon carbide region, the fifth silicon carbide region, the sixth silicon carbide region, and the seventh silicon carbide region and surrounding the first portion and the second portion;
a gate insulating layer provided between the first silicon carbide region, the second silicon carbide region, the third silicon carbide region, the fourth silicon carbide region, the fifth silicon carbide region, the sixth silicon carbide region, and the seventh silicon carbide region and the gate electrode; and
a second electrode provided on the second face side of the silicon carbide layer.

2. The semiconductor device according to claim 1,
wherein depths of the second silicon carbide region and the third silicon carbide region are larger than depths of the eighth silicon carbide region and the ninth silicon carbide region.

3. The semiconductor device according to claim 1,
wherein depths of the second silicon carbide region and the third silicon carbide region are equal to or more than two times and equal to or less than ten times depths of the eighth silicon carbide region and the ninth silicon carbide region.

4. The semiconductor device according to claim 1,
wherein depths of the second silicon carbide region and the third silicon carbide region are substantially the same as depths of the eighth silicon carbide region and the ninth silicon carbide region.

5. The semiconductor device according to claim 1,
wherein depths of the eighth silicon carbide region and the ninth silicon carbide region are equal to or more than 0.5 μm and equal to or less than 1 μm.

6. The semiconductor device according to claim 1,
wherein depths of the second silicon carbide region and the third silicon carbide region are equal to or more than 1 μm and equal to or less than 2 μm.

7. The semiconductor device according to claim 1,
wherein the eighth silicon carbide region or the ninth silicon carbide region is present on the first face in a third direction perpendicular to the first face of an end portion in the first direction of the gate electrode between the first portion and the second portion.

8. The semiconductor device according to claim 1,
wherein an end portion in the first direction of the gate electrode between the first portion and the second portion is provided directly above the eighth silicon carbide region or the ninth silicon carbide region of the first face.

9. The semiconductor device according to claim 1,
wherein an end portion in the first direction of the gate electrode between the first portion and the second portion overlaps the eighth silicon carbide region or the ninth silicon carbide region in the first direction.

10. The semiconductor device according to claim 1,
wherein a distance between the eighth silicon carbide region and the ninth silicon carbide region in the first direction is equal to or more than 1.5 times a length of the eighth silicon carbide region in the first direction.

11. The semiconductor device according to claim 1,
wherein a length of the eighth silicon carbide region in the first direction is equal to or more than 2 μm and equal to or less than 5 μm.

12. The semiconductor device according to claim 1,
wherein a distance between the eighth silicon carbide region and the ninth silicon carbide region in the first direction is equal to or more than twice a distance between the second silicon carbide region and the third silicon carbide region in the second direction.

13. The semiconductor device according to claim 1,
wherein a distance between the eighth silicon carbide region and the ninth silicon carbide region in the first direction is equal to or more than 5 μm and equal to or less than 100 μm.

14. The semiconductor device according to claim 1,
wherein the eighth silicon carbide region and the ninth silicon carbide region are in contact with the first face.

15. The semiconductor device according to claim 1,
wherein the silicon carbide layer further includes:
a tenth silicon carbide region of the second conductive type provided between the first silicon carbide region and the first face, extending in the first direction, and spaced apart from the fourth silicon carbide region in the second direction;
an eleventh silicon carbide region of the first conductive type provided between the tenth silicon carbide region and the first face and extending in the first direction;
a twelfth silicon carbide region of the second conductive type provided between the first silicon carbide region and the first face, provided between the fourth silicon carbide region and the tenth silicon carbide region, and in contact with the fourth silicon carbide region and the tenth silicon carbide region; and
a thirteenth silicon carbide region of the second conductive type provided between the first silicon carbide region and the first face, between the fourth silicon carbide region and the tenth silicon carbide region, in contact with the fourth silicon carbide region and the tenth silicon carbide region, and spaced apart from the twelfth silicon carbide region in the first direction,
the first electrode further includes a third portion in contact with the twelfth silicon carbide region and a fourth portion in contact with the thirteenth silicon carbide region, and
the gate electrode surrounds the third portion and the fourth portion.

16. The semiconductor device according to claim 15,
wherein the third portion is disposed in the second direction of the first portion, and the fourth portion is disposed in the second direction of the first portion.

17. The semiconductor device according to claim 15,
wherein a position of the third portion in the first direction is between a position of the first portion in the first direction and a position of the second portion in the first direction.

18. The semiconductor device according to claim 1,
wherein the silicon carbide layer further includes:
a tenth silicon carbide region of the second conductive type provided between the first silicon carbide region and the first face, provided between the third silicon carbide region and the fourth silicon carbide region, and in contact with the third silicon carbide region and the fourth silicon carbide region; and
an eleventh silicon carbide region of the second conductive type provided between the first silicon carbide region and the first face, provided between the third silicon carbide region and the fourth silicon carbide region, in contact with the third silicon carbide region and the fourth silicon carbide region, and spaced apart from the tenth silicon carbide region in the first direction,
the first electrode further includes a third portion in contact with the tenth silicon carbide region and a fourth portion in contact with the eleventh silicon carbide region,
the gate electrode surrounds the third portion and the fourth portion, and
a position of the third portion in the first direction is between a position of the first portion in the first direction and a position of the second portion in the first direction.

19. The semiconductor device according to claim 18,
wherein a distance between the tenth silicon carbide region and the eleventh silicon carbide region in the first direction is equal to or more than three times a length of the tenth silicon carbide region in the first direction.

20. The semiconductor device according to claim 1,
wherein the first conductive type is n-type, and the second conductive type is p-type.
